(19) United States
(12) Patent Application Publication
(10) Pub. No.: US 2026/0247535 A1
(43) Pub. Date: Aug. 20, 2026

(54) CIRCUIT BOARD FOR BYPASS DIODE, BYPASS DIODE DEVICE, AND SOLAR BATTERY MODULE

(71) Applicant: KYOCERA Corporation, Kyoto-shi (JP)

(72) Inventors: Masamitsu SHIBATA, Tokyo (JP); Takeshi KAZAMA, Yokohama-shi (JP); Yuji IINO, Shibushi-shi (JP)

(73) Assignee: KYOCERA Corporation, Kyoto-shi (JP)

(21) Appl. No.: 19/170,339

(22) Filed: Apr. 4, 2025

Related U.S. Application Data
(63) Continuation-in-part of application No. PCT/JP2024/028576, filed on Aug. 8, 2024.

(30) Foreign Application Priority Data
Oct. 6, 2023 (JP) 2023-174667

(51) Int. Cl. H05K 1/181; H05K 1/11

(52) U.S. Cl. CPC H05K 1/181; H05K 1/113; H05K 1/119; H05K 2201/09045; H05K 2201/094; H05K 2201/10037; H05K 2201/10143; H05K 2201/10174

(57) ABSTRACT

[Object] To make a circuit including a bypass diode small or thin.

[Solution] A circuit board for a bypass diode according to the present disclosure includes a ceramic substrate and a conductor. The conductor is disposed in the central region of a main surface of the ceramic substrate in a form of a single sheet in an island shape. The conductor includes a first electrode portion and a second electrode portion. The first electrode portion is provided with a bypass diode, and is an electrode for electrically connecting the bypass diode. The second electrode portion is a region of the conductor excluding the first electrode portion.

### CROSS-REFERENCE TO RELATED APPLICATIONS

This application is a continuation of International Application No. PCT/JP2024/028576 filed on Aug. 8, 2024 based on Japanese Patent Application No. 2023-174667 filed on Oct. 6, 2023, the entire contents of which are incorporated herein by reference.

### TECHNICAL FIELD

The present disclosure relates to a circuit board for a bypass diode, a bypass diode device, and a solar battery module.

### BACKGROUND OF INVENTION

In recent years, solar power generation has become widespread as renewable energy. Current solar battery modules are usually provided with a junction box on their back surface.

The junction box includes a bypass diode therein. The bypass diode has a role of protecting a solar battery cell by bypassing an electrical current when a failure such as shading of the solar battery module occurs (for example, see Japanese Patent Application Laid-Open No. 2015-185784).

### Solution to Problem

In one aspect of the present disclosure, a circuit board for a bypass diode includes a ceramic substrate, and a conductor. The conductor is disposed in a central region of a main surface of the ceramic substrate in the form of a single sheet in the shape of an island. The conductor includes a first electrode portion and a second electrode portion. The first electrode portion is provided with a bypass diode, and is an electrode for electrically connecting the bypass diode. The second electrode portion is a region of the conductor excluding the first electrode portion.

### BRIEF DESCRIPTION OF THE DRAWINGS

FIG. 1 is a cross-sectional view of a bypass diode device illustrated as an example of an embodiment.

FIG. 2 is a plan view of a ceramic substrate and a conductor illustrated as an example of the embodiment.

FIG. 3 is an exploded perspective view of the ceramic substrate and the conductor illustrated as an example of the embodiment.

FIG. 4 is a cross-sectional view of a solar battery module illustrated as an example of the embodiment.

FIG. 5 is a cross-sectional view illustrating another aspect of the circuit board for a bypass diode.

FIG. 6 is a cross-sectional view illustrating another aspect of the circuit board for a bypass diode.

FIG. 7 is a plan view of a ceramic substrate and a collective conductor portion illustrated in FIG. 6.

FIG. 8 is an exploded perspective view of the ceramic substrate and the collective conductor portion illustrated in FIG. 6.

FIG. 9 is a plan view of the circuit board for a bypass diode illustrated in FIG. 6.

FIG. 10 is a diagram illustrating a configuration in which a third electrode portion and a fourth electrode portion are provided on the back surface of the circuit board for a bypass diode illustrated in FIG. 6.

FIG. 11 is a cross-sectional view illustrating another aspect of the circuit board for a bypass diode.

FIG. 12 is a cross-sectional view illustrating another aspect of the circuit board for a bypass diode.

FIG. 13 is a cross-sectional view illustrating another aspect of the circuit board for a bypass diode.

FIG. 14 is a cross-sectional view illustrating another aspect of the circuit board for a bypass diode.

FIG. 15 is a cross-sectional view illustrating another aspect of the circuit board for a bypass diode.

FIG. 16 is a schematic view of an automobile equipped with a solar battery module.

### DESCRIPTION OF EMBODIMENTS

Hereinafter, the circuit board for a bypass diode, the bypass diode device using the circuit board, and the solar battery module according to the embodiment will be described with reference to the drawings. Note that, an aspect of the present disclosure is not limited to the specific embodiment described below. An aspect of the present disclosure is assumed to include various aspects provided that the aspect falls within the spirit or scope of the general inventive concepts as defined by the appended claims.

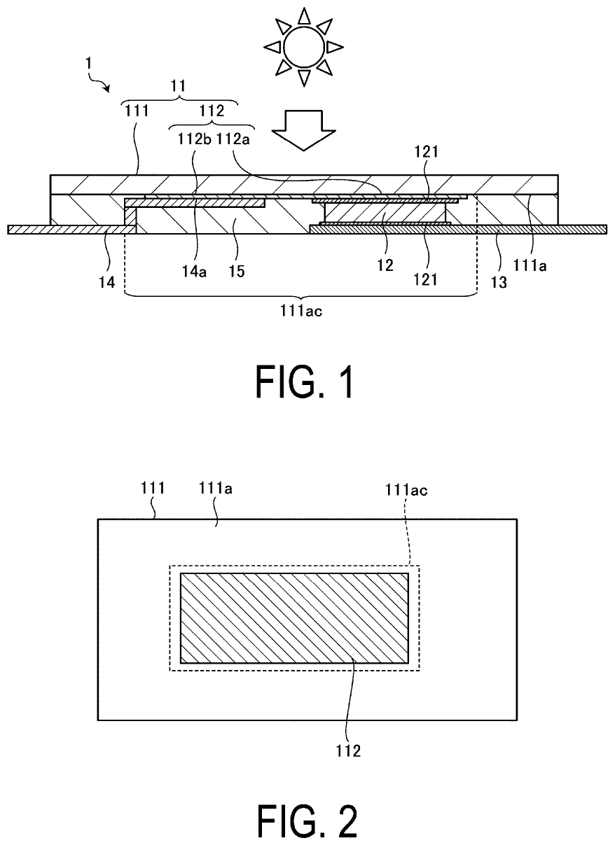

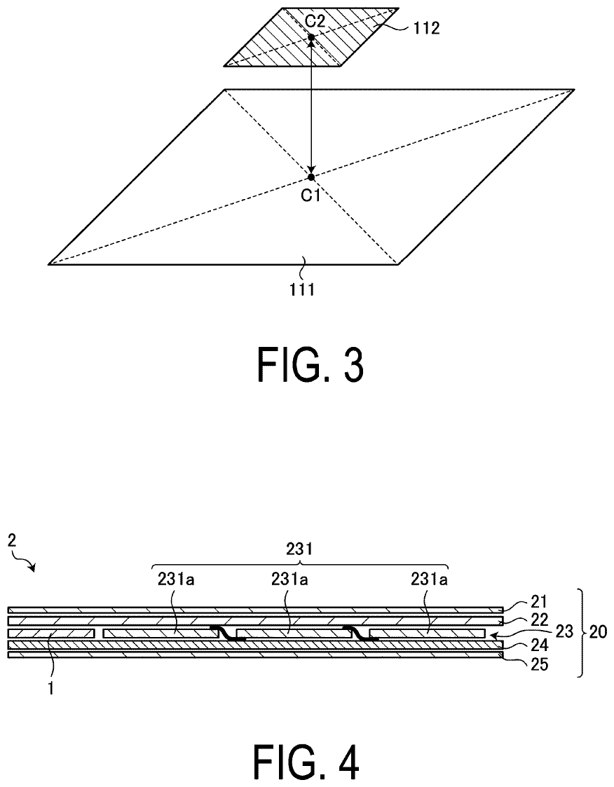

FIG. 1 is a cross-sectional view of the bypass diode device illustrated as an example of the embodiment. FIG. 2 is a plan view of the ceramic substrate and the conductor illustrated as an example of the embodiment. FIG. 3 is an exploded perspective view of the ceramic substrate and the conductor illustrated as an example of the embodiment. FIG. 4 is a cross-sectional view of the solar battery module illustrated as an example of the embodiment.

As illustrated in FIG. 1, a bypass diode device 1 illustrated as an example of the embodiment includes a circuit board 11 for a bypass diode and a bypass diode 12.

First, the circuit board 11 for a bypass diode will be described. The circuit board 11 for a bypass diode includes a ceramic substrate 111 and a conductor 112. The conductor 112 is disposed in a central region 111ac of a main surface 111a of the ceramic substrate 111 in the form of a single sheet in the shape of an island. The conductor 112 includes a first electrode portion 112a and a second electrode portion 112b.

Since the circuit board 11 for a bypass diode has a configuration in which the conductor 112 is merely disposed on the main surface 111a of the ceramic substrate 111, a circuit including the bypass diode 12 can be reduced in size or thickness.

As illustrated in FIG. 2, when the main surface 111a of the ceramic substrate 111 is likened to the sea, the conductor 112 is in a state like an isolated island floating in mid-ocean. The conductor 112 is present alone on the ceramic substrate 111. In the term of mid-ocean, no conductors other than the single sheet-like conductor 112 are present on the surface of the ceramic substrate 111. The conductor here may function as a part of a circuit. For example, the conductor may not include a conductor having no electrical function, such as an alignment mark formed by metallization.

On the main surface 111a of the ceramic substrate 111, the surface of the ceramic substrate 111 is exposed around the conductor 112. The central region 111a of the main surface 111ac of the ceramic substrate 111 is a region including a center point C1 of the ceramic substrate 111. As illustrated in FIG. 3, the center point C1 of the ceramic substrate 111 is, for example, a position at which two diagonal lines intersect when the diagonal lines are drawn so as to connect corners at diagonal positions among four corners of a quadrangle such as a square or a rectangle when the shape of the ceramic substrate 111 in plan view is the quadrangle.

In the conductor 112, when a center point C2 of the conductor 112 is obtained using the same method as in the case of the ceramic substrate 111 described above, the center point C2 is preferably disposed to overlap the center point C1 of the main surface 111a of the ceramic substrate 111, but the center point C2 of the conductor 112 does not necessarily overlap the center point C1 of the main surface 111a of the ceramic substrate 111, and may be displaced. For example, the center point C1 of the ceramic substrate 111 may be within a range of the area of the conductor 112.

The central region 111ac in the main surface 111a of the ceramic substrate 111 is a range including the center point C1 and having a predetermined area. As illustrated in FIG. 2, when the area of the ceramic substrate 111 is set to 100% in a plan view seen from a direction orthogonal to the main surface 111a, the area ratio of the central region 111ac can be set to about 10% or more and about 70% or less. The reason why the numerical range of the ratio of the area of the central region 111ac is given as an example is that the area of the conductor 112 formed on the ceramic substrate 111 affects the size of the bypass diode, the electrical characteristics such as electrical conductivity required for the circuit board 11 for a bypass diode, the mechanical strength of the circuit board 11 for a bypass diode itself, and the like, and it is better to give flexibility to the size including the thickness of the conductor 112 depending on the application.

In the circuit board 11 for a bypass diode of the present disclosure, the area of the conductor 112 is preferably 60% or less of the area of the main surface 111a of the ceramic substrate 111 in a plan view when the main surface 111a is viewed from a direction orthogonal to the main surface 111a. As an example of the range of the area ratio of the conductor 112, when the area of the ceramic substrate 111 is 100%, the lower limit value may be 10% and the upper limit value may be 60%. When the area ratio of the conductor 112 is expressed in another way, the area of the conductor 112 is 0.1 or more and 0.6 or less when the area of the main surface 111a of the ceramic substrate 111 is 1. The area of the conductor 112 in the main surface 111a of the ceramic substrate 111 is preferably smaller than the area where the conductor 112 is not present. When the area of the conductor 112 is 60% or less of the area of the main surface 111a of the ceramic substrate 111, the periphery of the conductor 112 of the main surface 111a is totally thin because of the absence of the conductor 112. Since the area of the conductor 112 is small, the thermal stress between the conductor 112 and the ceramic substrate 111 can be reduced, and the possibility of deformation or peeling of the conductor 112 can be reduced. On the other hand, when the area of the conductor 112 is 10% or more of the area of the main surface 111a of the ceramic substrate 111, the resistance value of the conductor 112 does not become excessively low.

In the structure in which the conductor 112 is disposed in the central region 111ac of the main surface 111a, portions without the conductor 112 are disposed symmetrically with respect to the conductor 112 located at the center in the main surface 111a. As a result, the circuit board 11 for a bypass diode is easily deflected symmetrically about the conductor 112 located in the central region 111ac of the main surface 111a. From another point of view, it can be said that the portions without the conductor 112 are disposed radially about the conductor 112. As a result, the circuit board 11 for a bypass diode is also easily deflected radially about the conductor 112 located in the central region 111ac of the main surface 111a. When the ceramic substrate 111 has a shape that is easily deflected radially about the conductor 112 in the main surface 111a, even when the ceramic substrate 111 is deformed, the ceramic substrate 111 surrounds the periphery (entire periphery) of the conductor 112 located in the central region 111ac, and stresses are dispersed. Thus, the ceramic substrate 111 has high durability.

The first electrode portion 112a of the conductor 112 is a portion (mounting portion) on which the bypass diode 12 is mounted. The first electrode portion 112a is an electrode for electrically connecting the bypass diode 12. The first electrode portion 112a is a member for fixing the bypass diode 12 to the ceramic substrate 111.

The second electrode portion 112b is basically a region of the conductor 112 other than the first electrode portion 112a. A conductive member such as a connection line is connected to the second electrode portion 112b. The first electrode portion 112a and the second electrode portion 112b are electrically connected to each other.

Since the conductor 112 is in the form of a single sheet on the main surface of the ceramic substrate 111, the first electrode portion 112a and the second electrode portion 112b constituting the conductor 112 have the same polarity. The first electrode portion 112a and the second electrode portion 112b have the same potential. That is, the first electrode portion 112a and the second electrode portion 112b have the same polarity and the same potential.

On the conductor 112, between the first electrode portion 112a and the second electrode portion 112b, a region may be present where the bypass diode 12 is not mounted or where a conductive member such as a connection line is not disposed.

The fact that the conductor 112 is in the form of a single sheet means that it forms an aspect of one metal film as illustrated in FIG. 1.

The conductor 112 may have different thicknesses between the first electrode portion 112a and the second electrode portion 112b. The conductor 112 may have portions with different thicknesses at arbitrary positions on the conductor 112 without specifying the first electrode portion 112a and the second electrode portion 112b.

When the conductor 112 has portions with different thicknesses, adjustment becomes possible between the height of the bypass diode 12 mounted on the first electrode portion 112a and the height of the conductive member connected to the second electrode portion 112b. An example is a case where it is desired to make the height of the bypass diode 12 and the height of the conductive member equal to each other or to make the difference between these heights small.

The second electrode portion 112b serves as a conductor portion for flowing electrical current to the outside of the circuit board 11 for a bypass diode. The second electrode portion 112b serves as a conductor portion for taking electrical current from the external circuit into the bypass diode 12. When electrically connected, they are coated with an organic resin 15, as illustrated in FIG. 1.

The material of the conductor 112 is preferably a metal having high electrical conductivity. Examples of the material of the conductor 112 include one selected from the group consisting of copper, tungsten, molybdenum, aluminum, iron, nickel, cobalt, solder (Sn—Pb), and noble metals. When copper and tungsten are used as the material of the conductor 112, they preferably include at least one selected from the group consisting of a mixed composition, an intermetallic compound, and an alloy after sintering.

The material of the conductor 112 preferably has a high thermal conductivity. In this case, copper and silver are preferable. As the material of the conductor 112, a material that can be co-fired with the ceramic substrate 111 may be selected. The conductor 112 may be formed by baking on the sintered ceramic substrate 111 in advance. When the conductor 112 is formed by baking, it is preferable to use a metal-containing composition which can be fixed at a temperature lower than the sintering temperature of the ceramic substrate 111. When a coating method, a printing method, or the like is used to form the metal-containing composition on the ceramic substrate 111, it is preferable to use a so-called paste in which metal powder and an organic vehicle are mixed.

As the shape of the ceramic substrate 111, an arbitrary shape can be selected according to the design of the bypass diode device 1 and the solar battery module 2 to which the bypass diode device 1 is mounted.

When the ceramic substrate 111 is viewed in a plan view, the basic shape of the ceramic substrate 111 may be a rectangular shape, a circular shape, an elliptical shape, or a polygonal shape other than a rectangular shape.

When the basic shape of the ceramic substrate 111 is a rectangular shape, a circular shape, an elliptical shape, or a polygonal shape other than a rectangular shape, the ceramic substrate 111 may have a recessed portion, a protruding portion, or the like at a corner portion or on a side between two corner portions forming the basic shape.

The material used for the ceramic substrate 111 may be a material containing as a main component at least one selected from the group consisting of alumina, mullite, silicon nitride, aluminum nitride, silica, forsterite, glass ceramics, and the like. When these materials are used, a ceramic substrate exhibiting high characteristics such as insulation property, mechanical strength, moisture resistance, weather resistance and chemical resistance can be obtained.

In a basic configuration of the bypass diode device 1 of the present disclosure, the bypass diode 12 is mounted on the conductor 112.

The bypass diode 12 is fixed to the circuit board 11 for a bypass diode via a bonding material 121. As the bonding material 121, solder, a conductive adhesive, or the like is selected, but a conductive adhesive containing metal particles in an organic resin may be selected in terms of thermal resistance.

In the bypass diode device 1 illustrated in FIG. 1, in addition to the bypass diode 12, a first electrode member 13 is bonded to the surface of the bypass diode 12. The first electrode member 13 is bonded to the surface of the bypass diode 12 via, for example, the bonding material 121.

In the bypass diode device 1 illustrated in FIG. 1, in addition to the bypass diode 12, a second electrode member 14 is bonded to the second electrode portion 112b. The bonding material is also used to bond the second electrode portion 112b to the second electrode member 14. Also in this case, the above-described bonding material 121 used for bonding the bypass diode 12 to the circuit board 11 for a bypass diode may be used, but a bonding material having a different melting temperature may be used. For example, when a bonding material having a melting temperature lower than the melting temperature of the bonding material 121 used for bonding the bypass diode 12 to the circuit board 11 for a bypass diode is used, the bonding material 121 is less likely to melt even when the second electrode member 14 is bonded to the second electrode portion 112b after the bypass diode 12 is bonded to the circuit board 11 for a bypass diode. Therefore, the bond between the bypass diode 12 and the circuit board 11 for a bypass diode can be maintained strong.

The portion of the second electrode member 14 adhered to the second electrode portion 112b (i.e., a bonding portion 14a) is preferably bonded to the second electrode portion 112b in such a manner that the surfaces thereof overlap each other. When the bonding portion 14a of the second electrode member 14 and the second electrode portion 112b are bonded to each other in a face-to-face manner, the contact area between the bonding portion 14a of the second electrode member 14 and the second electrode portion 112b can be increased. As a result, the electrical conductivity from the second electrode portion 112b to the second electrode member 14 can be increased.

The area ratio of the bonding portion 14a of the second electrode member 14 in contact with the second electrode portion 112b is preferably 40% or more and 90% or less when the area of the surface of the second electrode portion 112b facing the second electrode member 14 is 100%. When the area ratio of the second electrode member 14 to the second electrode portion 112b is 40% or more at the bonding surface between the second electrode member 14 and the second electrode portion 112b, the electrical conductivity can be increased, and in addition, the mechanical strength of the electrode portion can be improved since the bonding portion 14a of the second electrode member 14 and the second electrode portion 112b are overlapped and bonded. As a result, even when a thickness 111t of the ceramic substrate 111 is thin, the rigidity of the circuit board 11 for a bypass diode can be increased as a whole, and the bypass diode device 1 having high durability can be obtained.

The reason why the upper limit of the area ratio of the bonding portion 14a of the second electrode member 14 in contact with the second electrode portion 112b is set to 90% is that the bonding portion 14a of the second electrode member 14 remains within the plane of the second electrode portion 112b even when the bonding portion 14a of the second electrode member 14 and the second electrode portion 112b are displaced from each other in a direction parallel to the bonding surface when the bonding portion 14a of the second electrode member 14 and the second electrode portion 112b are overlapped with each other. In this way, the bonding portion 14a of the second electrode member 14 and the second electrode portion 112b can be firmly bonded to each other electrically and mechanically.

The bypass diode device 1 of the present disclosure is not limited thereto. In the bypass diode device 1 of the present disclosure, the bypass diode 12 may be mounted on the conductor 112.

The bypass diode 12 is a junction of a P-type semiconductor and an N-type semiconductor. FIG. 1 illustrates a configuration in which the bypass diode 12 is mounted on the first electrode portion 112a of the conductor 112 provided on the circuit board 11 for a bypass diode, but in the circuit board 11 for a bypass diode of the present disclosure, the mounting portion of the bypass diode 12 may be the second electrode portion 112b.

In the bypass diode device 1, as illustrated in FIG. 1, the bypass diode 12 may be disposed closer to an installation surface side than the ceramic substrate 111. Here, the installation surface side may be a side opposite to a side receiving sunlight.

FIG. 4 illustrated an example of the solar battery module 2. The solar battery module 2 illustrated in FIG. 4 includes a solar battery panel 20 and the bypass diode device 1. The solar battery panel 20 has a configuration in which a first film 21, a first resin layer 22, a cell group 23, a second resin layer 24, and a second film 25 are layered in this order.

The cell group 23 includes a plurality of series cell groups 231. Note that FIG. 4 illustrates only one series cell group 231. In the series cell group 231, a plurality of cells 231a are electrically connected in series. The series cell group 231 may have a portion in which these cells are connected in parallel in the cell group 23.

In the solar battery module 2 illustrated in FIG. 4, the first film 21 side is the surface on which sunlight is received. The second film 25 side is an installation surface side. The second film 25 side is also a side close to the installation surface. The first film 21 and the second film 25 are made of EVA (ethylene vinyl acetate), for example.

As illustrated in FIG. 4, when the bypass diode device 1 is incorporated into the solar battery module 2, the bypass diode device 1 may be disposed such that the bypass diode 12 faces downward. In other words, in the bypass diode device 1, the bypass diode 12 may be located on the opposite side to the position of the sun with the ceramic substrate 111 at the center when the solar battery module 2 to be installed on the object is considered to be installed in the direction perpendicular to the installation surface.

In a structure in which the bypass diode 12 is located on the side opposite to the position of the sun (the position where sunlight is received), the bypass diode device 1 is disposed so that the ceramic substrate 111 serves as a shielding plate and sunlight does not strike the bypass diode device 1.

Since the ceramic substrate 111 blocks sunlight, the temperature rise of the bypass diode 12 can be reduced. Since the time, frequency, and probability that the bypass diode 12 is exposed to sunlight are reduced, the deterioration of the bypass diode 12 due to the surrounding environment such as sunlight or dew condensation is suppressed.

The solar battery module 2 illustrated in FIG. 4 includes the solar battery panel 20 and the bypass diode device 1. In this case, the bypass diode device 1 is disposed on the second resin layer 24.

The bypass diode device 1 is disposed on the same plane as the cell group 23 on the second resin layer 24. The bypass diode device 1 is sandwiched between the first resin layer 22 and the second resin layer 24 on the same plane as the cell group 23.

The bypass diode device 1 is preferably disposed around the cell group 23 in the solar battery module 2. When the bypass diode device 1 is disposed around the cell group 23 in the solar battery module 2, the cell group 23 can be disposed in a concentrated manner in the plane, and thus the solar battery module 2 with high efficiency can be obtained.

For example, when the bypass diode device 1 is disposed on the inner side of the cell 231a located at the end in the plane of the cell group 23, a region in which no electromotive force is generated is generated in the cell group 23.

For example, when the bypass diode device 1 is disposed on the inner side of the cell 231a located at the end in the plane of the cell group 23, a portion is generated in which a conductive wire for electrically connecting the cells in the cell group 23 or the series cell groups 231 is long. This results in a decrease in electromotive force, a decrease in generated power, and a decrease in power generation efficiency per unit area.

The thickness of the bypass diode device 1 is preferably equal to or less than the thickness of the cell 231a or the cell group 23.

The area of the bypass diode device 1 in a plan view is preferably smaller than the area of one cell 231a in a plan view.

For example, when a conventional junction box is provided in the solar battery module 2, the junction box greatly protrudes from the back surface of the solar battery module 2. While, when the bypass diode device 1 of the present disclosure is used, the bypass diode device 1 falls within the range of the thickness of the cell group 23, and thus the flatness of both surfaces of the solar battery module 2 can be maintained.

When the solar battery module 2 is a so-called flat plate-shaped structure, a plurality of solar battery modules 2 can be layered without any gap in the layer direction. When the solar battery module 2 is a flat plate-shaped structure, the cell group 23 and the solar battery module 2 can be slightly bent and stacked. Since the bulk (volume) of the plurality of solar battery modules 2 can be reduced when they are transported, the efficiency of transportation is increased. When the solar battery module 2 is a so-called flat plate-shaped structure, the solar battery module 2 can be easily installed and fixed to a flat roof of a house, a vehicle, or the like.

The area of the first electrode portion 112a in a plan view is preferably larger than the area of the bonding surface of the bypass diode 12. Thus, heat generation caused by electrical conductivity generated in the circuit board 11 for a bypass diode can be reduced. In the circuit board 11 for a bypass diode, the resistance of the electrical current flowing into the bypass diode 12 or flowing out from the bypass diode 12 can be reduced. It is possible to suppress heat generation of the bypass diode 12 caused by connection with the conductor 112 of the circuit board 11 for a bypass diode.

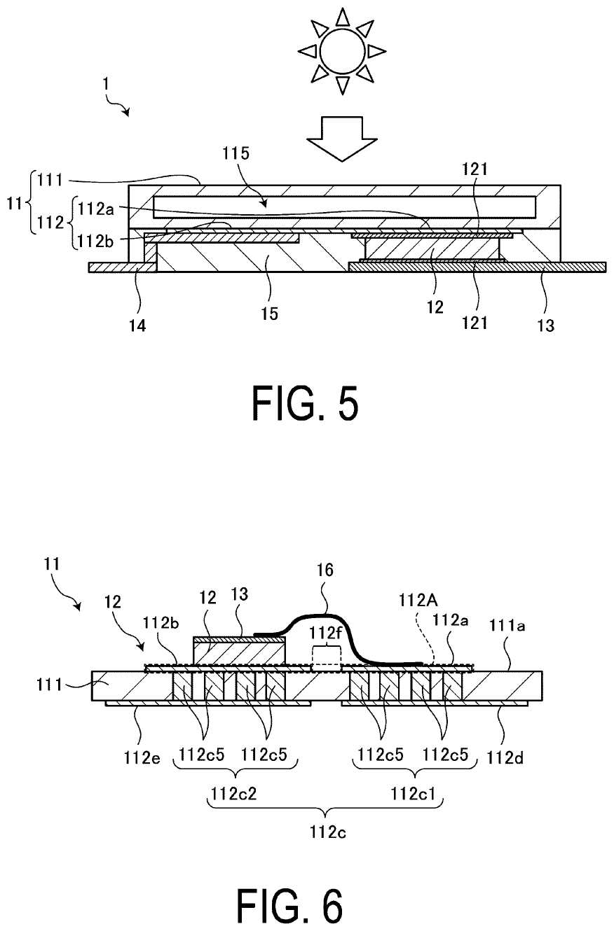

FIG. 5 is a cross-sectional view illustrating another aspect of the circuit board 11 for a bypass diode. In FIG. 5, in order to illustrate the positional relationship with the bypass diode 12, a configuration in which the bypass diode 12 is disposed as in FIG. 1 is illustrated for convenience.

As illustrated in FIG. 5, the ceramic substrate 111 may have therein a space portion 115 overlapping the conductor 112 in a plan view. In this case, the thermal conductivity of the ceramic substrate 111 can be reduced. In particular, when the surface opposite to the surface on which the conductor 112 is provided is the light receiving side of the solar battery module 2, heat diffusion can be suppressed from the light receiving side to the surface on which the conductor 112 is provided inside the ceramic substrate 111. Since the temperature rise of the bypass diode 12 can be suppressed, the operation of the bypass diode 12 can be stabilized and the useful life of the bypass diode 12 can be extended. The area of the space portion 115 in a plan view may be an area corresponding to the area of the conductor 112 in a plan view. The area of the space portion 115 in a plan view may be equal to or larger than the area of the conductor 112 in a plan view. In this case, the outer edge of the conductor 112 may be located inside the outer edge of the space portion 115 in a plan view. This can further reduce the thermal conductivity of the ceramic substrate 111.

Not limited to the example of FIG. 5, the space portion 115 may be partitioned into a plurality of spaces by a partition (not illustrated). In this case, the plurality of spaces may be disposed to overlap the conductor 112 in a plan view. In this case, the total area in which the plurality of spaces and the conductor 112 overlap may be 80% or more of the area of the conductor 112.

By partitioning the space portion into a plurality of spaces as described above, the strength of the ceramic substrate 111 can be improved. That is, the strength of the ceramic substrate 111 can be improved without increasing the total thickness, and the thermal conductivity can be reduced.

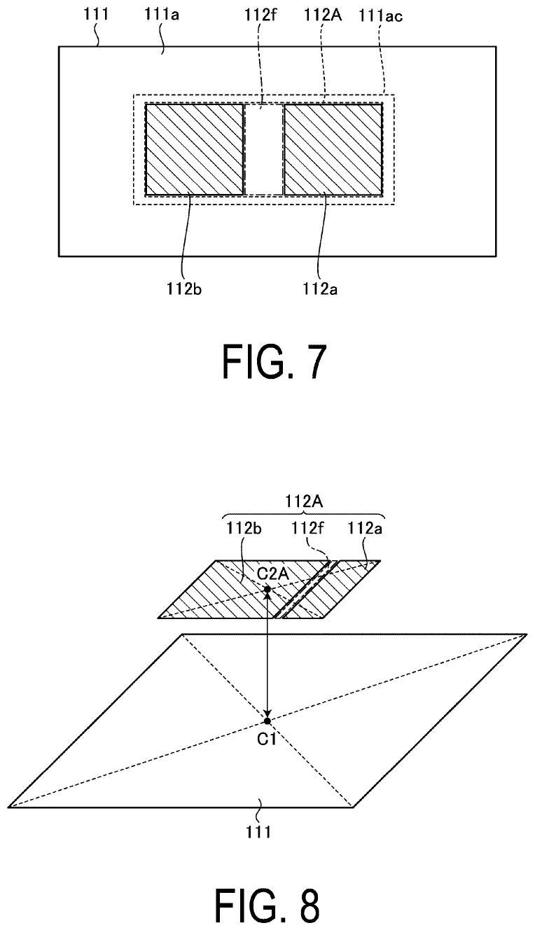

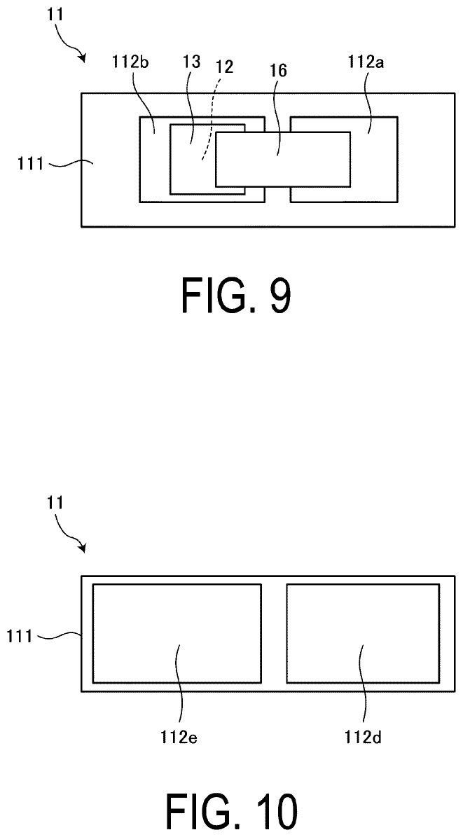

FIG. 6 is a cross-sectional view illustrating another aspect of the circuit board 11 for a bypass diode. FIG. 7 is a plan view of the ceramic substrate and the collective conductor portion illustrated in FIG. 6. FIG. 8 is an exploded perspective view of the ceramic substrate and the collective conductor portion illustrated in FIG. 6. FIG. 9 is a plan view of the circuit board for a bypass diode illustrated in FIG. 6. FIG. 10 is a diagram illustrating a configuration in which the third electrode portion and the fourth electrode portion are provided on the back surface of the circuit board 11 for a bypass diode illustrated in FIG. 6. Note that FIG. 8 is different from FIGS. 6 and 7 in the sizes of the first electrode portion 112a and the second electrode portion 112b.

In FIG. 6, the first electrode member 13 is bonded to the upper surface of the bypass diode 12. Although not illustrated, the bypass diode 12 includes a first terminal electrode on one surface thereof and a second terminal electrode on the other surface thereof.

In the circuit board 11 for a bypass diode illustrated in FIG. 6, the conductor 112 is divided into two parts as compared with the circuit board 11 for a bypass diode illustrated in FIG. 1. The conductor 112 includes a collective electrode portion 112A in the central region 111ac of the main surface 111a of the ceramic substrate 111. Here, as illustrated in FIG. 7, the collective electrode portion 112A is a conductor in which two electrode portions, the first electrode portion 112a and the second electrode portion 112b, are close to each other. In this case, the collective electrode portion 112A includes the first electrode portion 112a, the second electrode portion 112b, and an insulated region (referred to as an insulation region 112f) between the first electrode portion 112a and the second electrode portion 112b.

The collective electrode portion 112A is disposed in the central region 111ac of the main surface 111a of the ceramic substrate 111 in the shape of an island. In other words, the first electrode portion 112a and the second electrode portion 112b are provided in the central region 111ac of the main surface 111a of the ceramic substrate 111 to form the shape of an island. The area ratio of the collective electrode portion 112A to the main surface 111a of the ceramic substrate 111 is in the same or similar range as in the case of the single sheet-like conductor 112 described above. The central region 111ac of the main surface 111a of the ceramic substrate 111 in the circuit board 11 for a bypass diode illustrated in FIG. 7 is defined in the same or similar manner as in the case of the single sheet-like conductor 112 described above. That is, also in this case, the central region 111ac in the main surface 111a of the ceramic substrate 111 is a range including the center point C1 and having a predetermined area.

The ratio of the area of the central region 111ac can be about 10% or more and about 70% or less when the area of the ceramic substrate 111 is set to 100%. Here, the reason why the numerical value range of the ratio of the area of the central region 111ac is given as an example is that the area of the conductor 112 formed on the ceramic substrate 111 affects the size of the bypass diode, electrical characteristics such as conductivity required for the circuit board 11 for a bypass diode, the mechanical strength of the circuit board 11 for a bypass diode itself, and the like, and it is better to have some flexibility in the size of the conductor, including the thickness thereof, depending on the application.

In the circuit board 11 for a bypass diode of the present disclosure, the area of the collective electrode portion 112A which is the conductor 112 is preferably 60% or less of the area of the main surface 111a of the ceramic substrate 111. Also in this case, as an example of the range of the area ratio of the collective electrode portion 112A, when the area of the ceramic substrate 111 is 100%, the lower limit value may be 10% and the upper limit value may be 60%. In other words, when the area of the main surface 111a of the ceramic substrate 111 is 1, the area of the collective electrode portion 112A is 0.1 or more and 0.6 or less. The area of the collective electrode portion 112A on the main surface 111a of the ceramic substrate 111 is preferably smaller than the area where the collective electrode portion 112A is not present. When the area of the collective electrode portion 112A is 60% or less of the area of the main surface 111a of the ceramic substrate 111, the periphery of the collective electrode portion 112A on the main surface 111a is totally thin because of the absence of the conductor 112.

In the structure in which the collective electrode portion 112A is disposed in the central region 111ac of the main surface 111a, in the main surface 111a, the portions without the collective electrode portion 112A are disposed symmetrically with respect to the collective electrode portion 112A located at the center. As a result, the circuit board 11 for a bypass diode is easily deflected symmetrically with respect to the collective electrode portion 112A located in the central region 111ac of the main surface 111a. From another viewpoint, it can be said that the portions without the collective electrode portion 112A are disposed radially about the collective electrode portion 112A. In this case, as illustrated in FIG. 8, the first electrode portion 112a and the second electrode portion 112b constituting the collective electrode portion 112A may have different areas. As a result, the circuit board 11 for a bypass diode is also easily deflected radially about the collective electrode portion 112A located in the central region 111ac of the main surface 111a. Even when the ceramic substrate 111 is deformed, when the ceramic substrate 111 has a shape that is easily deflected radially about the collective electrode portion 112A of the main surface 111a, stresses are dispersed in the ceramic substrate 111 so as to surround the periphery (entire periphery) of the collective electrode portion 112A located in the central region 111ac, even when the ceramic substrate 111 is deformed. Also in the collective electrode portion 112A, the ceramic substrate 111 has high durability.

Since the first electrode portion 112a and the second electrode portion 112b are separated from each other into two, the first electrode portion 112a and the second electrode portion 112b can be reduced in size. Thus, the thermal stress due to the difference in thermal expansion between the ceramic substrate 111 and the conductor 112 can be reduced. Stress can be dispersed. As a result, deflection or deformation is less likely to occur, and thus the circuit board 11 for a bypass diode has excellent durability.

A center point C2A of the collective electrode portion 112A and the center point C1 of the ceramic substrate 111 may be displaced from each other as in the case of the single sheet-like conductor 112 described above. That is, also in this case, as in the case of the single sheet-like conductor 112, when the center point C2A of the collective electrode portion 112A is determined, the center point C2A is preferably disposed to overlap the center point C1 of the main surface 111a of the ceramic substrate 111, but the center point C2A of the collective electrode portion 112A does not necessarily overlap the center point C1 of the main surface 111a of the ceramic substrate 111 and may be displaced therefrom. For example, the center point C1 of the ceramic substrate 111 may be within a range of the area of the collective electrode portion 112A.

The first electrode portion 112a and the second electrode portion 112b constituting the conductor 112 (in this case, the collective electrode portion 112A) are spaced apart from each other on the ceramic substrate 111 to be insulated from each other. One of the first electrode portion 112a and the second electrode portion 112b serves as a mounting portion of the bypass diode 12. FIG. 6 illustrates an example in which the second electrode portion 112b serves as the mounting portion of the bypass diode 12. Note that the present invention is not limited to the example of FIG. 6, and the first electrode portion 112a may be the mounting portion of the bypass diodes 12. One of the first electrode portion 112a and the second electrode portion 112b, which is not the mounting portion of the bypass diode 12 serves as an electrode portion to which an external circuit for causing a current to flow outside the circuit board 11 for a bypass diode is to be electrically connected.

In the example of FIG. 6, the bypass diode 12 may be located on the opposite side of the position of the sun (not illustrated) with the ceramic substrate 111 in the middle. In this case, one of the first electrode portion 112a and the second electrode portion 112b, which is not the mounting portion of the bypass diode 12 may serve as an electrode portion to be connected to the external circuit.

The bypass diode 12 may be located on the same side as the position of the sun (not illustrated) with respect to the ceramic substrate 111. In this case, a third electrode portion 112d and a fourth electrode portion 112e described later may serve as electrode portions to be connected to the external circuit.

The ceramic substrate 111 may include a through-hole conductor portion 112c that penetrates the substrate in the thickness direction. The through-hole conductor portion 112c includes a plurality of through-hole conductors 112c5. The plurality of through-hole conductors 112c5 are electrically connected to the first electrode portion 112a and the second electrode portion 112b.

Also in this case, since the circuit board 11 for a bypass diode has a configuration in which two electrode portions are disposed on the main surface of the ceramic substrate 111, a circuit including the bypass diode 12 can be reduced in size or thickness. Since the ceramic substrate 111 includes the through-hole conductor portion 112c penetrating therethrough in the thickness direction, heat generated when the bypass diode 12 itself generates heat is easily transferred to the side opposite to the mounting portion of the bypass diode 12 on the ceramic substrate 111.

As illustrated in FIG. 6, the circuit board 11 for a bypass diode may further include the third electrode portion 112d and the fourth electrode portion 112e. The third electrode portion 112d is provided at a position opposite to the first electrode portion 112a via the ceramic substrate 111. The fourth electrode portion 112e is provided at a position opposite to the second electrode portion 112b via the ceramic substrate 111.

In other words, the third electrode portion 112d and the fourth electrode portion 112e are disposed on the back surface side of the ceramic substrate 111. When the ceramic substrate 111 is viewed in cross-section, the third electrode portion 112d and the fourth electrode portion 112e are preferably positioned symmetrically on the back surface of the ceramic substrate 111. In a plan view seen from a direction orthogonal to the back surface of the ceramic substrate 111, the third electrode portion 112d and the fourth electrode portion 112e preferably have the same area. When the ceramic substrate 111 is viewed in cross-section, the third electrode portion 112d and the fourth electrode portion 112e are preferably symmetrical with respect to the conductor 112 or the collective electrode portion 112A located in the central region 111ac of the main surface 111a in terms of positioning and area relationship.

The through-hole conductor portion 112c includes a first through-hole conductor portion 112c1 and a second through-hole conductor portion 112c2. The first electrode portion 112a and the third electrode portion 112d are electrically connected via the first through-hole conductor portion 112c1. The second electrode portion 112b and the fourth electrode portion 112e are electrically connected to each other via the second through-hole conductor portion 112c2. Each of the first through-hole conductor portion 112c1 and the second through-hole conductor portion 112c2 may be formed by the plurality of through-hole conductors 112c5.

The first through-hole conductor portion 112c1 and the second through-hole conductor portion 112c2 are preferably disposed to be within the planes of the first electrode portion 112a and the second electrode portion 112b, respectively. This means that even when the collective electrode portion 112A is formed on the main surface 111a of the ceramic substrate 111, no conductors are present around the collective electrode portion 112A. As a result, even when the ceramic substrate 111 includes the through-hole conductor portion 112c, the circuit board 11 for a bypass diode is easily deflected radially about the collective electrode portion 112A and the through-hole conductor portion 112c located in the central region 111ac of the main surface 111a. When the ceramic substrate 111 has a shape that is easily deflected radially about the collective electrode portion 112A in the main surface 111a, even when the ceramic substrate 111 is deformed, stresses are dispersed so that the ceramic substrate 111 surrounds the periphery (entire periphery) of the collective electrode portion 112A and the through-hole conductor portion 112c located in the central region 111ac. The ceramic substrate 111 can have high durability even when the through-hole conductor portion 112c is added to the collective electrode portion 112A.

For example, when the bypass diode 12 is disposed on the second electrode portion 112b of the ceramic substrate 111 and the first terminal electrode of the bypass diode 12 is electrically connected to the second electrode portion 112b, the second terminal electrode of the bypass diode 12 is electrically connected to the first electrode portion 112a via a bonding wire 16.

The area of the third electrode portion 112d in plan view is preferably larger than the area of the region of the first through-hole conductor portion 112c1 in plan view. The area of the fourth electrode portion 112e in plan view is preferably larger than the area of the region of the second through-hole conductor portion 112c2 in plan view. The area of the third electrode portion 112d in plan view may be larger than the area of the first electrode portion 112a in plan view. The area of the fourth electrode portion 112e in plan view may be larger than the area of the second electrode portion 112b in plan view. In this case, heat is easily dissipated from the back surface side of the ceramic substrate 111 opposite to the mounting portion of the bypass diode 12. Electrode structures may be disposed symmetrically.

The color tone of the ceramic substrate 111 is either black-based or white-based. When the color tone of the ceramic substrate 111 is black-based, the color tone is the same color tone as that of the solar cell, and thus the design is not impaired. When the color tone of the ceramic substrate 111 is white-based, sunlight is easily reflected, and thus an element does not easily reach a high temperature.

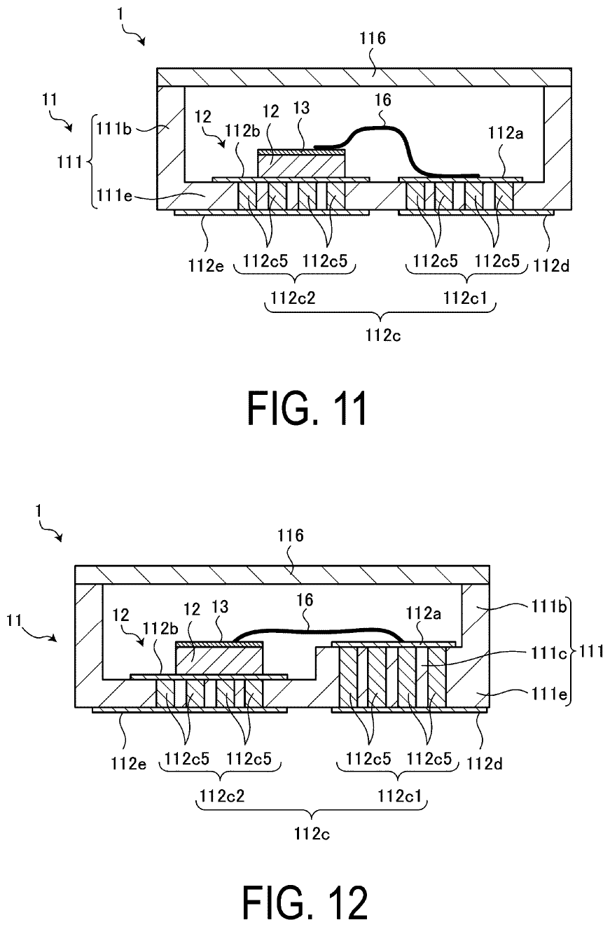

FIG. 11 is a cross-sectional view illustrating another embodiment of the circuit board 11 for a bypass diode. In FIG. 11, in order to show the arrangement of the bypass diode 12 in a bank portion 111b, FIG. 11 illustrates a configuration in which the bypass diode 12 is disposed in the mounting portion and a lid 116 is disposed. The configuration illustrated in FIG. 11 is also the bypass diode device 1.

The ceramic substrate 111 may include a flat plate-shaped body portion 111e on which the conductor 112 and the mounting portion of the bypass diode 12 are provided, and the bank portion 111b (wall member). The bank portion 111b is disposed at the peripheral edge portion of the body portion 111e of the ceramic substrate 111 so as to circumferentially surround the mounting portions of the conductor 112 and the bypass diode 12.

When the circuit board 11 for a bypass diode has a cavity structure with the bank portion 111b in which the lid 116 is to be placed on the bank portion 111b, it is not necessary to resin-seal the bypass diode 12 and the bonding wire 16 disposed on the ceramic substrate 111, and thus the possibility of reducing the height is higher than in the case of resin-sealing. In other words, when the circuit board 11 for a bypass diode is a structure including the bank portion 111b, the lid 116 may be disposed on the upper surface of the bank portion 111b.

In this case, the bypass diode 12 may be located on the same side as the position of the sun (not illustrated) with respect to the ceramic substrate 111. At this time, the third electrode portion 112d and the fourth electrode portion 112e may be electrode portions to be connected to an external circuit.

The bypass diode 12 may be located on a side opposite to the position of the sun (a position where sunlight is received). As a result, the bypass diode device 1 is disposed such that the ceramic substrate 111 serves as a shielding plate and is not exposed to sunlight.

In the case illustrated in FIG. 6, the bank portion 111b and the mounting region of the bypass diode 12 inside the lid 116 are filled with gas such as air. In the case of gas, since the thermal conductivity is lower than that of resin-seal, heat generated from the bypass diode 12 is easily transmitted to the ceramic substrate 111 and the through-hole conductor portion 112c. In the solar battery module 2, when the lid 116 is disposed to be in contact with the solar battery panel 20, heat of the bypass diode 12 is easily dissipated to the space on the back surface side of the solar battery panel 20 by the through-hole conductor portion 112c.

The material of the lid 116 may be the same ceramic material as that of the ceramic substrate 111 as long as it is a dense body capable of enhancing airtightness, but may be a metal material. The metal material preferably has a coefficient of thermal expansion close to that of the ceramic substrate 111. For example, kovar (Fe—Ni—Co) may be used. The coefficient of thermal expansion of kovar is 4.5 to 5×10⁻6/° C.

FIG. 12 is a cross-sectional view illustrating another embodiment of the circuit board 11 for a bypass diode. In FIG. 12, a part of the mounting portion located inside the bank portion 111b includes a step structure. FIG. 12 also illustrates a configuration in which the bypass diode 12 is disposed in the mounting portion for convenience. The configuration illustrated in FIG. 12 is also the bypass diode device 1.

The bank portion 111b has a step structure including one step portion 111c. To be specific, the bank portion 111b includes the step portion 111c between the mounting surface of the body portion 111e of the ceramic substrate 111 and the upper surface of the bank portion 111b. On the upper surface of the step portion 111c, an electrical conductor film (fifth electrode portion, here, first electrode portion 112a) is located.

Since the connection position of the bonding wire 16 on the side of the circuit board 11 for a bypass diode is close to the height of the bypass diode 12, the length of the bonding wire 16 can be shortened. Thus, the resistance of the bonding wire 16 can be reduced.

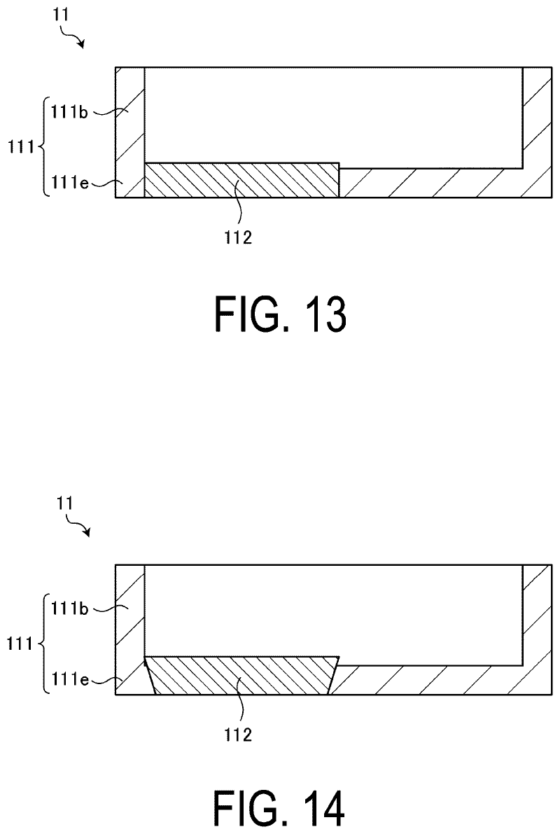

FIGS. 13 and 14 are cross-sectional views illustrating other aspects of the circuit board 11 for a bypass diode. As illustrated in FIGS. 13 and 14, the conductor 112 may penetrate the ceramic substrate 111. When the conductor 112 penetrates the ceramic substrate 111 in the thickness direction, the heat of the bypass diode 12 (not illustrated here) mounted on the mounting portion on the conductor 112 can be directly released to the back surface side of the ceramic substrate 111 via the penetrating conductor 112.

In the conductor 112, the area of the mounting portion, the plane perspective area of the portion penetrating the ceramic substrate 111 in the thickness direction, and the area exposed on the back surface of the ceramic substrate 111 may be substantially the same (FIG. 13). The shape of the longitudinal section of the conductor 112 may be a trapezoidal shape (not illustrated) or an inverted trapezoidal shape (see FIG. 14) from the mounting portion side to the back surface side of the ceramic substrate 111. In other words, the width of the conductor 112 may change from the mounting portion side to the back surface side of the ceramic substrate 111. In this case, the conductor 112 is not easily removed from the ceramic substrate 111. When the mounting portion is on the solar battery panel 20 side, the shape of the longitudinal section of the conductor 112 is preferably a trapezoidal shape. As a result, since the heat of the bypass diode 12 is conducted to the back surface side of the ceramic substrate 111 while being diffused in the lateral direction of the conductor 112, the thermal conductivity is enhanced, and the heat radiation property toward the back surface of the ceramic substrate 111 can be enhanced.

When the mounting portion is on the installation surface side opposite to the solar battery panel 20, the shape of the longitudinal section of the conductor 112 is preferably an inverted trapezoidal shape. As illustrated in FIG. 14, when the shape of the longitudinal section of the conductor 112 is an inverted trapezoidal shape, the conductor 112 is preferably disposed such that the upper surface (with smaller area) of the trapezoidal shape is on the installation surface side.

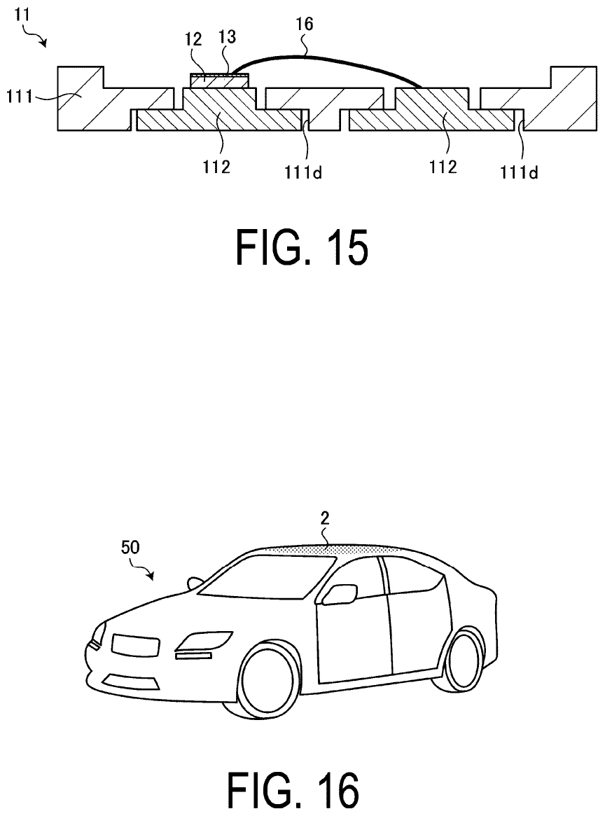

FIG. 15 is a cross-sectional view illustrating another aspect of the circuit board 11 for a bypass diode. In the circuit board 11 for a bypass diode illustrated in FIG. 14, the cross-sectional shape of the conductor 112 may be protruding. In this case, the protruding conductor 112 may penetrate the ceramic substrate 111. Since the conductor 112 is protruding, a through hole 111d of the ceramic substrate 111 has a shape in which the protruding conductor 112 is fitted.

The protruding conductor 112 is disposed to be fitted into the recessed through hole 111d with respect to the step of the ceramic substrate 111. In the circuit board 11 for a bypass diode illustrated in FIG. 15, two protruding conductors 112 are disposed in two recessed through holes 111d provided in the ceramic substrate 111 and having a step, respectively.

One of the protruding conductors 112 serves as a mounting portion for mounting the bypass diode 12. As illustrated in FIG. 15, the other protruding conductor 112 serves as a connecting portion for connecting the bonding wire 16 extending from the bypass diode 12. As illustrated in FIG. 15, the other protruding conductor 112 serves as a terminal or an electrode for connecting the bonding wire 16 extending from the bypass diode 12.

The circuit board 11 for a bypass diode illustrated in FIG. 15 has a shape which widens on the side opposite to the installation surface of the bypass diode 12. Therefore, the heat of the bypass diode 12 is conducted to the back surface side of the ceramic substrate 111 while being diffused in the lateral direction of the conductor 112, and thus the thermal conductivity is enhanced, and the heat radiation property toward the back surface of the ceramic substrate 111 can be enhanced. The electrical resistance of the conductor 112 can be reduced. In this case, the two conductors 112 preferably have the same shape and volume. Stress such as thermal stress generated in the plane of the ceramic substrate 111 can be made symmetrical when FIG. 14 is viewed from the front side to the back side of the paper surface. Note that the expression “the same shape and volume” means that the shape or dimension of each side, corner, or ridge may be slightly changed as long as the protruding shape can be regarded as a basic shape when viewed from a far distance.

As illustrated in FIG. 1, the bypass diode device 1 includes the bypass diode 12 on any one of the circuit boards 11 for a bypass diode described above. Since the bypass diode device 1 uses the thin circuit board 11 for a bypass diode, the thin or small bypass diode device 1 can be obtained as compared with the conventional junction box type.

As illustrated in FIG. 4, the solar battery module 2 includes the solar battery panel 20 and the bypass diode device 1. Since the bypass diode device 1 uses the thin circuit board 11 for a bypass diode, the solar battery module 2 is finished into the thin solar battery module 2 having a structure which does not protrude from the solar battery panel 20, which is typical in a conventional junction box type.

As described above, the solar battery panel 20, the first film 21, the first resin layer 22 (transparent resin layer), the cell group 23 (solar battery cell), the second resin layer 24 (white resin layer), and the second film 25 are layered in this order. The bypass diode device 1 is accommodated within the range of the thickness of the solar battery panel 20. As a result, the solar battery module 2 has an appearance of a plate-shaped body having an equal thickness.

The solar battery module 2 of the present disclosure can reduce transportation costs or improve installation properties in automotive applications and the like. FIG. 16 is a schematic view of an automobile 50 on which the solar battery module 2 is mounted. According to the solar battery module 2 of the present disclosure, the roof of the automobile 50 can have a flatter structure.

### EXAMPLES

The relationship between the produced samples 1 to 7 and the drawings is as follows. Sample 1, sample 2, sample 3, sample 4, sample 5, sample 6, and sample 7 correspond to the circuit boards for a bypass diode illustrated in FIGS. 1, 6, 11, 12, 13, 14, and 5, respectively.

The area of each sample in a plan view was 10 mm×7 mm. The thickness of each sample (ceramic substrate) was 0.5 mm. In the circuit board for a bypass diode with the bank portion provided on the ceramic substrate, the height of the bank portion was 0.5 mm. The thickness of the conductor was 0.1 mm.

Green sheets containing various ceramic powders of alumina, aluminum nitride, and glass ceramics were prepared.

Conductive patterns having predetermined areas were formed on these green sheets. Note that, through holes were formed in the green sheets as needed. Thus, a circuit board for a bypass diode including a through-hole conductor portion (including a plurality of through-hole conductors) or a conductor penetrating the green sheet was produced. As a firing condition, the usual firing condition when the above-described ceramic powders were used was employed.

The conductive pattern was formed so that the area ratio of the conductor or the collective electrode portion in each sample of the circuit board for a bypass diode was 60%. In the collective electrode portion, the area of the electrode portion on which the bypass diode was mounted was about twice the area of the electrode portion on which the bypass diode was not mounted. The planar shape of the conductor or the collective electrode portion of each sample was rectangular, and the conductive pattern was formed so as to have a shape similar to the planar shape of the ceramic substrate.

Alumina was used as the ceramic powder, and a mixed composition of copper and tungsten was used as the conductor material. Aluminum nitride was used as the ceramic powder, and tungsten was used as the conductor material. Glass ceramics was used as the ceramic powder, and copper was used as the conductor material.

When the circuit board for a bypass diode was a structure including a bank portion, a method of layering a frame-shaped body cut out from the green sheet on a plate-shaped green sheet was employed to produce the structure. The bypass diode was mounted on the conductor of each of the circuit boards for a bypass diode thus produced with a resin adhesive (solder is also acceptable).

As the bypass diode, a type was prepared in which the shape of the element was a rectangular parallelepiped and the terminal electrodes were formed to cover substantially the entire surfaces of both main surfaces thereof. For connection to the conductor (electrode portion) of the bypass diode, a combination of a metal film and a resin adhesive (solder is also acceptable) was used.

Samples 1 to 3 were produced from the green sheets using alumina and glass ceramics. Samples 4 to 7 were produced from the green sheets using aluminum nitride.

Bypass diodes were mounted on the samples 1, 2, 3, 4 and 7 (among them, a lid (kovar) was used for a circuit board for a bypass diode including a bank portion) to produce bypass diode devices, which were attached to solar battery panels to produce solar battery modules.

The solar battery modules incorporating any of the bypass diode devices had the same thickness and did not have a conventional projection due to the junction box. It has been found that, in terms of design, even when the solar battery modules are mounted on the roof of an automobile, no portion protrudes into the interior of the automobile.

The ceramic substrate used for the produced sample was subjected to a deflection test using an autograph. In the deflection test, a method was used in which the periphery of the produced circuit board for a bypass diode was fixed and the central region where the conductor was disposed was pressed.

In each of the samples, it was confirmed that the conductor portion had a recessed shape, and the ceramic substrate was deflected. It has been found that the solar battery module can also be installed along even the curved surface of the roof of an automobile.

Note that the present technique can also have the following configurations.
(1)

A circuit board for a bypass diode including:
a ceramic substrate; and
a conductor;
wherein the conductor is disposed in a central region of a main surface of the ceramic substrate in a form of a single sheet in an island shape,
the conductor includes a first electrode portion and a second electrode portion,
the first electrode portion is provided with a bypass diode and electrically connects the bypass diode, and
the second electrode portion is a region of the conductor excluding the first electrode portion.
(2)

The circuit board for a bypass diode according to (1), wherein an area of the first electrode portion is larger than an area of a bonding surface of the bypass diode.
(3)

The circuit board for a bypass diode according to (1) or (2), wherein the ceramic substrate includes therein a space portion overlapping with the conductor in a plan view.
(4)

A circuit board for a bypass diode including:
a ceramic substrate; and
a conductor;
wherein the conductor includes a first electrode portion and a second electrode portion disposed close to each other in a central region of a main surface of the ceramic substrate, the first electrode portion and the second electrode portion being provided in an island shape, and
one of the first electrode portion and the second electrode portion serves as a mounting portion of a bypass diode.
(5)

The circuit board for a bypass diode according to any one of (1) to (4), wherein a color tone of the ceramic substrate is one of a black-based color tone and a white-based color tone.
(6)

The circuit board for a bypass diode according to any one of (1) to (5),
wherein the ceramic substrate includes a bank portion, and
the bank portion is disposed on a peripheral edge portion of the ceramic substrate to circumferentially surround the conductor and a mounting portion of the bypass diode.
(7)

The circuit board for a bypass diode according to (6), wherein the bank portion has a step structure including one step portion, and the step portion includes an electrical conductor film.
(8)

The circuit board for a bypass diode according to any one of (1) to (7), wherein the conductor includes a portion penetrating the ceramic substrate in a thickness direction.
(9)

A bypass diode device including the bypass diode on the circuit board for a bypass diode according to any one of (1) to (8).
(10)

A solar battery module including:
the bypass diode device according to (9); and
a solar battery panel.
(11)

The solar battery module according to claim 10,
wherein the solar battery panel includes a first film, a transparent resin layer, a solar battery cell, a white resin layer, and a second film layered in this order, and
the bypass diode device is contained within a range of a thickness of the solar battery panel.

Note that the embodiments disclosed herein are exemplary in all respects and not restrictive. The aforementioned embodiments can be embodied in a variety of forms. The above-described embodiments may be omitted, substituted or modified in various forms without departing from the scope and spirit of the appended claims.

1. A circuit board for a bypass diode comprising:
a ceramic substrate; and
a conductor; wherein
the conductor is disposed in a central region of a main surface of the ceramic substrate in a form of a single sheet in an island shape,
the conductor comprises a first electrode portion and a second electrode portion,
the first electrode portion is provided with a bypass diode and electrically connects the bypass diode, and
the second electrode portion is a region of the conductor excluding the first electrode portion.

2. The circuit board for a bypass diode according to claim 1, wherein
an area of the first electrode portion is larger than an area of a bonding surface of the bypass diode.

3. The circuit board for a bypass diode according to claim 1, wherein
the ceramic substrate comprises therein a space portion overlapping with the conductor in a plan view.

4. A circuit board for a bypass diode comprising:
a ceramic substrate; and
a conductor; wherein
the conductor comprises a first electrode portion and a second electrode portion disposed close to each other in a central region of a main surface of the ceramic substrate, the first electrode portion and the second electrode portion being provided in an island shape, and
one of the first electrode portion and the second electrode portion serves as a mounting portion of a bypass diode.

5. The circuit board for a bypass diode according to claim 1, wherein
a color tone of the ceramic substrate is one of a black-based color tone and a white-based color tone.

6. The circuit board for a bypass diode according to claim 1, wherein
the ceramic substrate comprises a bank portion, and
the bank portion is disposed on a peripheral edge portion of the ceramic substrate to circumferentially surround the conductor and a mounting portion of the bypass diode.

7. The circuit board for a bypass diode according to claim 6, wherein
the bank portion has a step structure comprising one step portion, and the step portion comprises an electrical conductor film.

8. The circuit board for a bypass diode according to claim 4, wherein
the conductor comprises a portion penetrating the ceramic substrate in a thickness direction.

9. A bypass diode device comprising:
the bypass diode on the circuit board for a bypass diode according to claim 1.

10. A solar battery module comprising:
the bypass diode device according to claim 9; and
a solar battery panel.

11. The solar battery module according to claim 10, wherein
the solar battery panel comprises a first film, a transparent resin layer, a solar battery cell, a white resin layer, and a second film layered in this order, and
the bypass diode device is contained within a range of a thickness of the solar battery panel.
